(19) United States
(12) Patent Application Publication
(10) Pub. No.: US 2013/0252350 A1
(43) Pub. Date: Sep. 26, 2013

(54) SYSTEM AND METHOD FOR GENERATING CARE AREAS FOR DEFECT INSPECTION

(71) Applicants: Hun Chow LEE, Singapore (SG); Shyue Fong QUEK, Singapore (SG); Seng-Keong Victor LIM, Singapore (SG); Fang Hong GN, Singapore (SG)

(72) Inventors: Hun Chow LEE, Singapore (SG); Shyue Fong QUEK, Singapore (SG); Seng-Keong Victor LIM, Singapore (SG); Fang Hong GN, Singapore (SG)

(73) Assignee: GLOBALFOUNDRIES SINGAPORE PTE. LTD., Singapore (SG)

(21) Appl. No.: 13/429,463

(22) Filed: Mar. 26, 2012

(51) Int. Cl. H01L 21/66; G06F 17/50

(52) U.S. Cl. 438/14; 716/112; 257/E21.53

(57) ABSTRACT

A method of generating care areas is disclosed. An artwork file of a layout of a product is provided and a cell tree of the layout is formed. The cell tree includes a plurality of cells of the layout arranged in a hierarchical order. The method also includes defining care areas in the artwork file of the layout.

### BACKGROUND

Defect inspection to detect manufacturing defects of semiconductor wafers has become a standard part of micro-fabrication manufacturing processes. To set up the inspection process, typical systems require the user to manually define care areas on the die of the wafer. Care areas are the areas where the user is interested in inspecting for defects of interest (DOI), such as the array areas.

The care area generation process is generally very tedious and error-prone. For example, a physical wafer is required to be loaded into an inspection tool. The user then analyzes the design pattern on the wafer and manually defines the inspection care areas. In order to maximize inspection sensitivity, it is common to have more than 10,000 care areas defined in, for example, a static random access memory (SRAM) region, to allow for multiple thresholds. As a result, the user may spend numerous hours to define care areas. Moreover, it is difficult to suppress the nuisance defect while maintaining DOI detection.

As such, what is needed is an improved technique for identifying inspection care areas on wafers.

### SUMMARY

A method of generating care areas is disclosed. An artwork file of a layout of a product is provided and a cell tree of the layout is formed. The cell tree includes a plurality of cells of the layout arranged in a hierarchical order. The method also includes defining care areas in the artwork file of the layout.

In another embodiment, a method of forming a device is presented. The method includes providing a wafer having a plurality of devices formed thereon. It also includes providing an inspection tool for inspecting the wafer for defects. The inspection tool contains information of care areas for inspection. The care areas are determined by forming a cell tree of cells in a hierarchical order of a layout of the device representing the plurality of devices from an artwork file of the device. The care areas on the wafer are inspected.

In yet another embodiment, a computer program storage medium is disclosed. The computer program storage medium includes a program with instructions to determine care areas of a layout of a device. The instructions include reading an artwork file containing the layout of the device, creating a hierarchical cell tree which is a logical representation of the cells of the device, and identifying the care areas of the device from the cell tree.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows a wafer;

FIG. 2 shows a rendering of a cell from an artwork file;

FIGS. 3a-b show an embodiment of a process for generating care areas;

FIG. 3c shows a graphical illustration of a process of FIG. 3b;

FIG. 4 shows an embodiment of a hierarchical cell tree;

FIGS. 5a-b illustrate care areas in a product artwork file; and

FIG. 6 shows an embodiment of defect detection.

### DETAILED DESCRIPTION

The following description sets forth techniques that facilitate automatic generation of care areas for defect inspection. Embodiments relate to care areas for defect inspection of wafers used in the fabrication process of semiconductor devices.

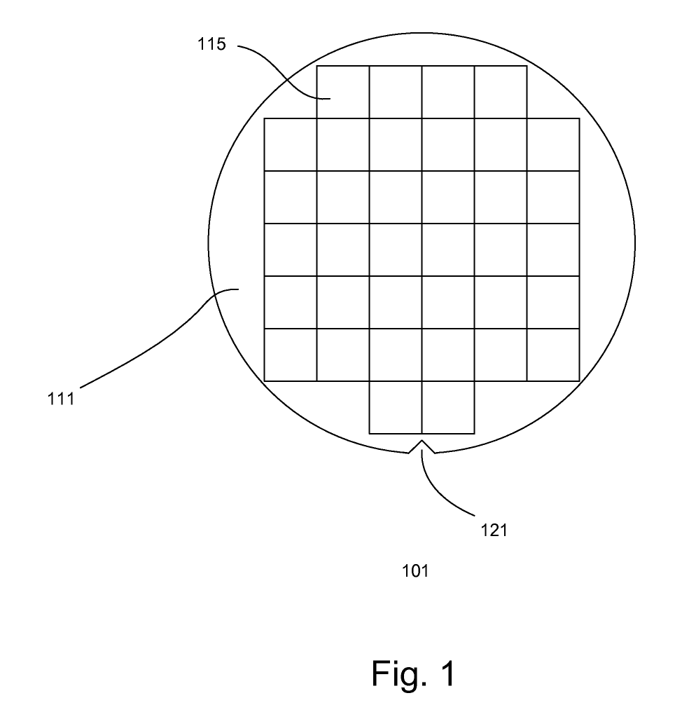

FIG. 1 shows a semiconductor wafer 101. The semiconductor wafer, for example, includes silicon. Other types of wafers are also useful. For example, the wafer may be a p-type, n-type, silicon-on-insulator or silicon germanium wafer. Depending on the type of device, the wafer may include a non-semiconductor material. The wafer may include a notch 121 to indicate the crystal orientation of the wafer. Other techniques for indicating the crystal orientation may also be useful. Additional indicators may also be included to indicate the dopant type of the wafer.

The wafer includes an active surface 111 on which devices 115 are formed. A plurality of devices may be formed on the wafer in parallel. The devices are subsequently singulated into individual dies, assembled and tested. In other embodiments, the wafer may include a single device.

The fabrication of devices, such as integrated circuits (ICs), involves the formation of features on a substrate that make up circuit components, such as transistors, resistors and capacitors. The devices are interconnected, enabling the device to perform the desired functions. Interconnections are formed by forming contacts and conductive lines in a dielectric layer using, for example, damascene techniques. Devices may include a plurality of interconnect levels.

The various features and interconnections are strategically placed on the device to minimize the use of space and/or optimize performance. The placement of various features and interconnections is referred to as a product or device layout.

The product layout is contained in an artwork file. The artwork file contains 3-dimensional information of the product layer. For example, the various layers of the product are contained in the artwork file. The artwork file can be various types of artwork file. The artwork file, for example, can be a GDSII, LEF, DEG, OASIS or CIF type of file. Other types of artwork file may also be useful.

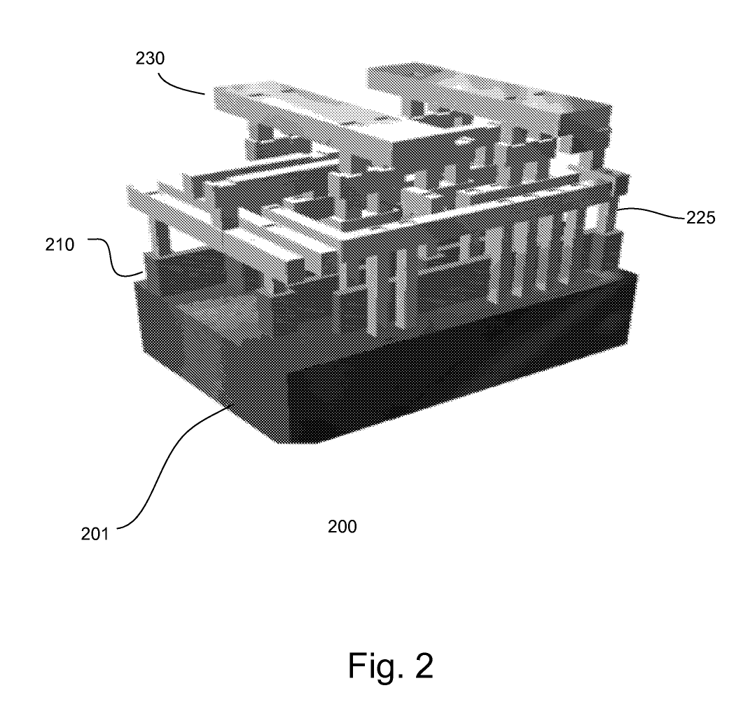

FIG. 2 illustrates a 3-dimensional rendering of a GDSII standard cell layout 200. The cell includes a substrate 201 with a patterned polysilicon layer 210 which forms polysilicon lines which represent gate electrodes of transistors. Three metal layers 230 are provided in the cell. The metal layers are coupled to the substrate and gates by contacts represented by posts 225.

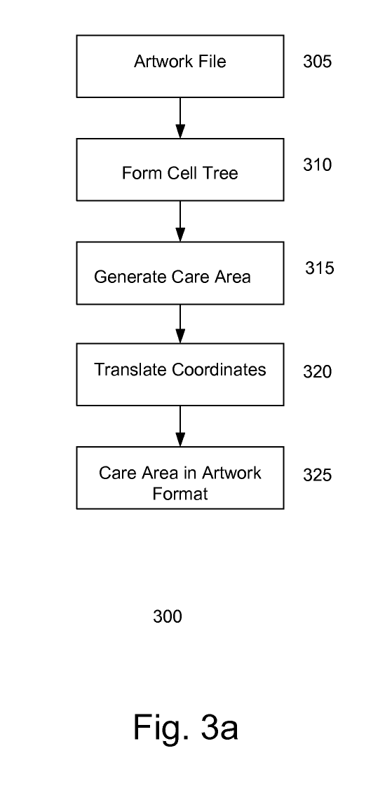

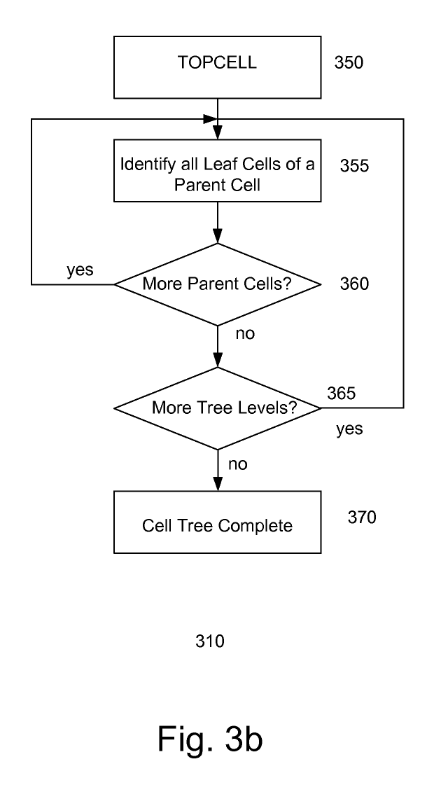

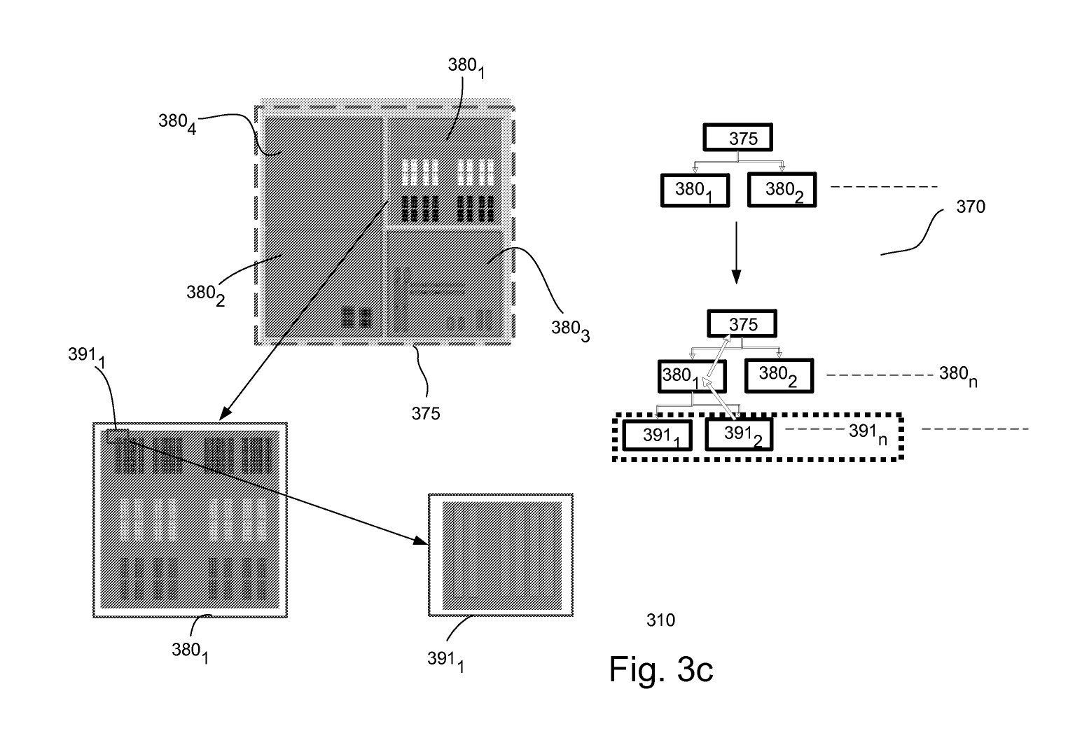

FIG. 3a illustrates an exemplary method 300 of generating care areas of a device. In one embodiment, the care areas are generated from design data. “Design data” generally refers to data derived or contained in an artwork file representing a layout of the device of interest. This methodological implementation may be performed in software, hardware, or a combination thereof. For ease of understanding, the method steps are delineated as separate steps; however, these separately delineated steps should not be construed as necessarily order-dependent in their performance or as distinct steps.

At step 305, an artwork file containing a layout of the product is obtained. The artwork file, for example, may be in GDSII format. Providing an artwork file in other formats, such as OASIS, may also be useful. GDSII and OASIS are binary file formats. In other embodiments, the artwork file may be in a predefined text format or a combination of formats. For example, the artwork file may be in GDSII and OASIS.

The artwork file contains design data of a layout of the product in hierarchical form which can be used to reconstruct the artwork. For example, the design data is a hierarchy of structures containing elements situated on layers. The design data is contained in a library or record of cells. Cells may contain geometrical objects, such as polygons, paths and other cells. Objects in a cell are assigned to layers of the layout.

The design data is input into a processor for processing at step 310. The processor, in one embodiment, flattens the design data to a 2-dimensional layout with information of the various layers provided as a single layer. The design data is processed to form a cell tree. For example, the processor constructs a database of a logical tree structure of cells. The cell tree corresponds to a logical presentation of the layout.

The cell at the highest level of the cell tree is referred to as the TOPCELL. The TOPCELL, for example, corresponds to the whole product. The TOPCELL may have numerous branches. A branch may have any number of levels. For example, a branch may have three levels, including the top level. Providing a branch with other number of levels may also be useful. Additionally, branches in the tree need not have the same number of levels. For example, some branches may have three levels while others may have four levels. A cell which has a lower level is referred to a PARENTCELL with respect to the cells at the higher level. The cell at a lower level of a PARENTCELL is referred to as a LEAFCELL. A PARENTCELL should have at least two LEAFCELLs or two branches. The cells at the lowest level of the cell tree are LEAFCELLs of the cell tree. Other configurations of the cell tree may also be useful.

In one embodiment, the design data is processed using electronic design automation (EDA) software. The EDA software, for example, may include Mentor Graphics Calibre, Synopsys Hercules, or Cadence Assura. Using other types of EDA software may also be useful. A script may be created to instruct the EDA software to create the cell tree.

At step 315, the care area of the product layout is defined or generated. In one embodiment, the care area is the combined boundaries of the LEAFCELLs in the TOPCELL. For example, the care area is defined as a polygon or polygons of combined LEAFCELL boundaries in the TOPCELL. A boundary of a LEAFCELL is represented by coordinates indicating the spatial location of the boundary in the layout. The spaces between the LEAFCELLs represent the don't care area. The LEAFCELLs may be LEAFCELLs of the TOPCELLL. In other embodiments, the LEAFCELLs may be LEAFCELLs of PARENTCELLs disposed at an intermediate level of the cell tree. In some embodiments, the care area is a combination of LEAFCELLs of the TOPCELL and PARENTCELLs at one or more intermediate levels of the cell tree. In one embodiment, a scanline technique is employed to determine boundaries of LEAFCELLs for combining to define the care area. Alternatively, a sorting technique can be used to trace the boundaries of the LEAFCELLs for combining to define the care area. Such techniques, for example, are described in Lauther, “An O (N log N) Algorithm For Boolean Mask Operations”, IEEE 18th Design Automation Conf., pages 555-562. 1981; and Carlson et al., “A Scanline Data Structure Processor for VLSI Geometry Checking”, IEEE Transactions on Computer-Aided Design, vol. CAD-6, No. 5, September 1987, which are all incorporated by reference for all purposes.

The process continues to step 320 to determine whether the x-y coordinates of the artwork need to be translated. For example, the x-y coordinates of the artwork may have different orientations from the layout on the wafer. In such case, the coordinates need to be rotated to match the layout on the wafer. Additionally, coordinates may need to be shifted to match different die locations of the wafer. At step 325, the care areas are generated in the artwork file format.

As described, the generation of care areas is achieved without the existence of a physical wafer. This enables care area analysis to be performed once the artwork is completed, expediting the development and manufacturing process. Furthermore, the present process can significantly reduce the time needed for care area definition. Additionally, the number of care areas can be adjusted to achieve the desired sensitivity of the area of interest and nuisance noise. For example, larger number of care areas increases sensitivity of the area of interest and reduces the nuisance generated by open regions. The number of care areas in the TOPCELL can be increased or decreased, depending on the level that the LEAFCELLs are combined. For example, there would be a larger number of care areas when LEAFCELLs of intermediate PARENTCELLs are used as compared to LEAFCELLs of the TOPCELL.

FIG. 3b shows an embodiment of a process 310 for forming a hierarchical cell tree. At step 350, the TOPCELL cell boundary is determined. At step 355, LEAFCELLs of a PARENTCELL are identified. For the first iteration (e.g., x=1), the PARENTCELL is the TOPCELL, encompassing the product layout. Since there is only one PARENTCELL for the first iteration, there would be no more PARENTCELLs to analyze at step 360. The process then continues to 365 to determine if there are more tree levels to analyze. If there are, the process returns to step 355 and repeats until no more tree levels are left to analyze at step 365. When no more tree levels are left to analyze, the process terminates at step 370 with the completion of the cell tree.

FIG. 3c is a graphical illustration of an exemplary process 310, as depicted in FIG. 3b, for forming a logical cell tree 370 from an artwork file 305 containing a layout of a device. Referring to FIGS. 3b-c, the design data is processed at step 350 to define a TOPCELL 375 of the device. For example, the boundary of the TOPCELL can be determined using techniques, such as scanline or sorting techniques, as previously described. At step 355, LEAFCELLs 380₁₋ₙ, of the TOPCELL are identified. As shown, the TOPCELL includes LEAFCELLs 380₁₋₄. The LEAFCELLs 380₁₋₄ of the TOPCELL are analyzed at steps 355 and 360 to determine corresponding LEAFCELLs. For example, PARENTCELL 380₁ is analyzed to determine its corresponding LEAFCELLs 391₁₋ₙ. Likewise, other PARENTCELLs at the level below the TOPCELL are analyzed to determine their corresponding LEAFCELLs.

The process or processes of FIG. 3a-b may be in the form of a computer program. The computer program may include customized scripts to perform the desired function, such as EDA programs with customized scripts. The computer program may be stored in a computer medium. For example, the computer program may be stored in compact disks, magnetic tapes, or other types of storage media. In some cases, the program may be obtained from a main storage facility through, for example, the internet.

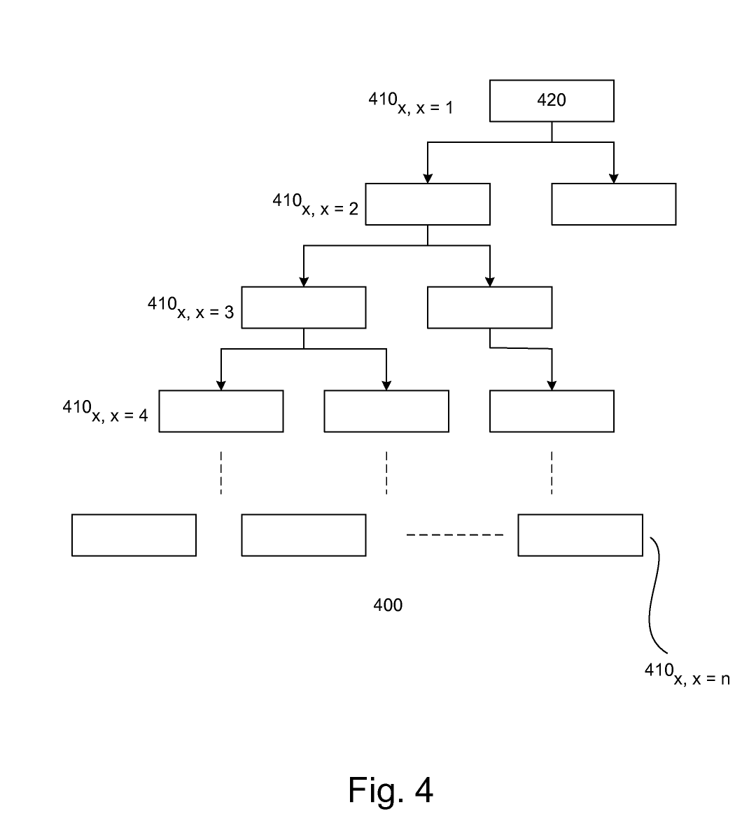

FIG. 4 shows a hierarchical cell tree 400 having a plurality of cells 420 arranged in different levels 410ₓ, where x is a whole number from 1-n. The top level (x=1) includes a TOPCELL which is the whole device or product layout. A cell at the lowest level (x=n) includes a unit or LEAFCELL cell. A cell at the x^{th} level vis-à-vis a related cell at the x^{th}-1 level is referred to as a parent. A related cell is part of the PARENTCELL prior to being divided. Cell or cells related to a PARENTCELL at the x^{th}-1 level are referred to as child or LEAFCELLs vis-à-vis the PARENTCELL.

As shown, the top level cell (x=1) includes two second level (x=2) LEAFCELLs. One of the second level cells is a PARENTCELL comprising two third level (x=3) cells while the other one does not have any third level cells. As for the third level cells, one is a PARENTCELL with two fourth level (x=4) LEAFCELLs while the other does not have any. The hierarchical cell tree continues to the lowest level (x=n). Other configurations of hierarchical cell trees are also useful, and may depend on the product layout.

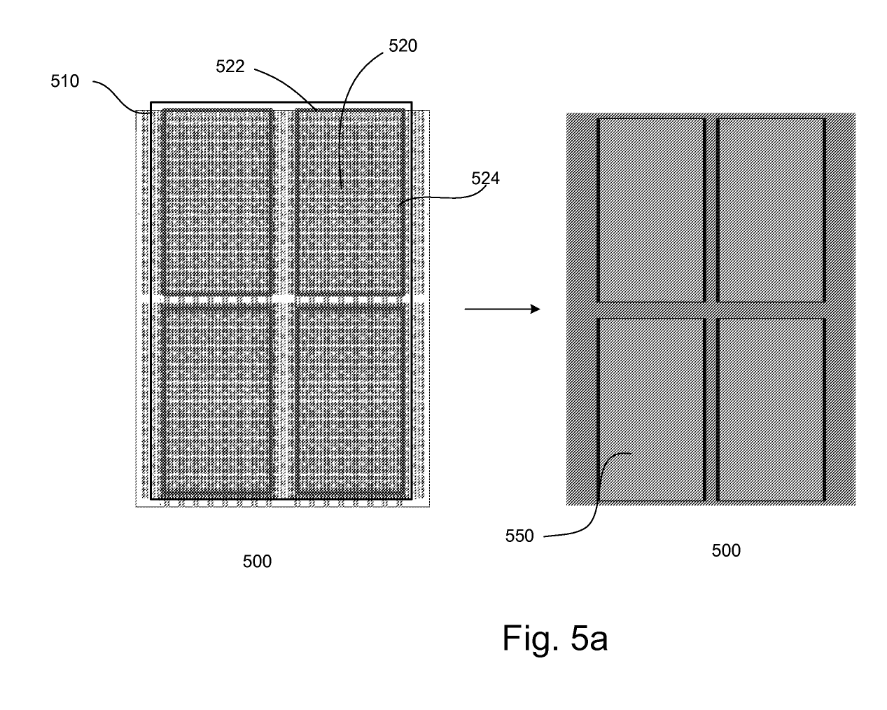

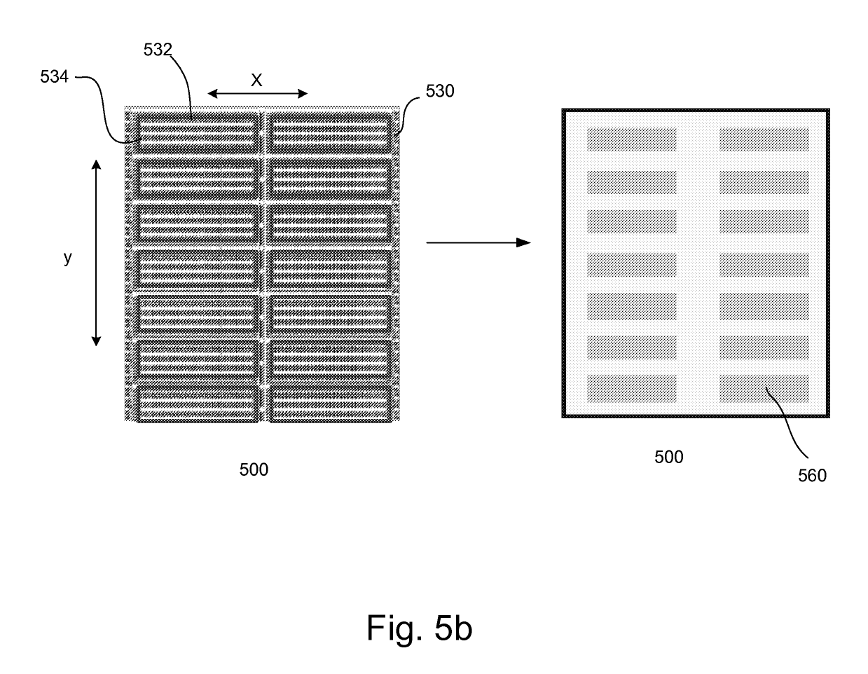

FIGS. 5a-b illustrate examples of care area generation. Referring to FIG. 5a, a product layout 500 is shown. The product layout includes a TOPCELL 510 which encompasses the layout of the product. Within the TOPCELL are LEAFCELLs 520. Illustratively, four leaf cells are provided within the TOPCELL. These leaf cells are cells at, for example, level 2 (e.g., x=2) of the hierarchical cell tree. For care areas at level 2, the x and y boundaries 522 and 524 of the level 2 cells are identified and combined to form polygons. In one embodiment, the user desires to define care areas at the second level. This results in the artwork having four care areas 550.

FIG. 5b shows a product layout 500 as shown in FIG. 5a. The LEAFCELLs 530 are derived from PARENTCELLs at the second level of the cell tree. That is, the LEAFCELLs are at the third level of the cell tree. In the case where the user desires to define care areas at the third level (e.g., x=3), the x and y boundaries 532 and 534 are combined to form polygons. This results in the artwork having 14 care areas 560.

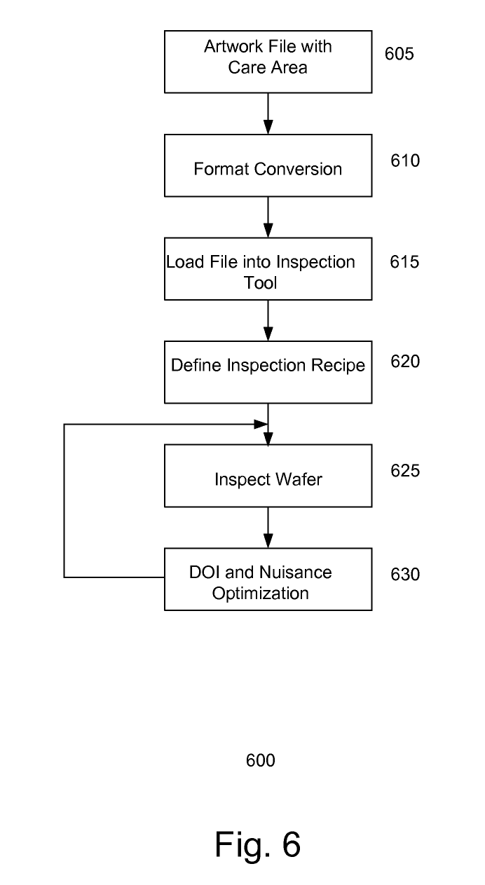

FIG. 6 shows an embodiment of a process for detecting defects. At step 605, the artwork file with care areas is provided. The file is converted into a compatible format for use with an inspection tool of interest at step 610. The inspection tool may be an inspection tool from KLA or HMI. Other types of inspection tools are also useful. The artwork file, for example, may be converted into the XML format. Converting the artwork file into other formats may also be useful and may depend on the type of inspection tool.

The output of the format conversion is a compatible file with care and don't care areas. The care and don't care areas, for example, are in the form of rectangular polygons. Providing care and don't care areas in other shapes may also be useful. For example, the care and don't care areas may be in non-rectangular polygons. The don't care areas may be the areas between the care areas. At step 615, the converted file is input into the inspection tool. For example, the file can be loaded into the inspection tool using conventional techniques, such as via network or via a storage medium on which the file is stored.

With the care and don't care areas defined in the inspection tool, the inspection parameters may be set. The inspection recipe is defined for the inspection tool at step 620. The inspection tool is programmed with the inspection recipe. In one embodiment, the inspection recipe includes parameters or settings from a best known method inspection recipe. The best known method inspection recipe, for example, is used for the initial scan. Inspection recipe parameters, for example, are threshold parameters used for the initial scan of a wafer which contains devices of the artwork file. For the initial scan, the threshold values are generally set low to capture both defects of interest and nuisance.

The inspection tool, at step 625, inspects a wafer on which devices are formed. The devices, for example, are devices associated with the artwork file. The inspection is based on the care area definition and the initial inspection recipe provided. Based on the scan results, the inspection recipe may be adjusted at step 630. For example, the inspection recipe may be modified to improve capturing defects of interst while truncating nuisances. The steps of 625 and 630 may be repeated until the desired defect of interest regions are localized and high nuisance regions are masked off.

If no weak points are detected by the final scan, the mask set used to form the devices on the wafer are qualified and used in production to form devices. In the event that weak points are detected by the final scan, the mask set used to form the devices on the wafer may be repaired or retrofitted until no weak points are detected. Wafers using the qualified mask set are produced. The devices on the wafer are separated into individual devices.

By providing an artwork file with care areas, inspection recipes can be more easily formed. Furthermore, critical and non-critical areas can be quickly identified through analysis of the artwork file. This enables inspection recipes to be more effectively tailored to produce more accurate inspection results.

Although the one or more above-described implementations have been described in language specific to structural features and/or methodological steps, it is to be understood that other implementations may be practiced without the specific features or steps described. Rather, the specific features and steps are disclosed as preferred forms of one or more implementations.

What is claimed is:

1. A method of generating care areas comprising:
providing an artwork file of a layout of a product;
forming a cell tree of the layout, wherein the cell tree comprises a plurality of cells of the layout arranged in a hierarchical order; and
defining care areas in the artwork file of the layout.

2. The method of claim 1 wherein forming the cell tree comprises:
determining a top level cell of the layout; and
determining child cells of the top level cell.

3. The method of claim 2 wherein the care areas are polygons in the top level cell corresponding to the child cells.

4. The method of claim 1 wherein forming the cell tree comprises:
determining a top level cell of the layout; and
determining child cells of the top level cell, wherein the top level cell comprises 1 to n child cells, where n is greater or equal to 2, wherein one child cell represents one branch of the tree branches from the top level cell.

5. The method of claim 4 comprises:
determining child cells of a branch until the lowest level of the tree cell for the branch is reached; and
repeating determining child cells of a branch for other branches until the lowest level of the tree is reached for all branches.

6. The method of claim 5 wherein the care areas are polygons in the top level cell corresponding to the lowest level cells of the branches.

7. The method of claim 1 wherein the care areas are polygons in the top level cell corresponding to lower level cells of the cell tree.

8. A method of forming a device comprising:
providing a wafer having a plurality of devices formed thereon;
providing an inspection tool for inspecting the wafer for defects, wherein the inspection tool contains information of care areas for inspection, wherein the care areas are determined by
forming a cell tree of cells in a hierarchical order of a layout of the device representing the plurality of devices from an artwork file of the device; and
inspecting the care areas on the wafer.

9. The method of claim 8 comprises dicing the wafer to separate the devices into individual devices.

10. The method of claim 8 wherein forming the cell tree comprises:
determining a top level cell of the layout; and
determining child cells of the top level cell.

11. The method of claim 10 wherein the care areas are polygons in the top level cell corresponding to the child cells.

12. The method of claim 8 comprises:
determining child cells of a branch until the lowest level of the tree cell for the branch is reached; and
repeating determining child cells of a branch for other branches until the lowest level of the tree is reached for all branches.

13. The method of claim 12 wherein the care areas are polygons in the top level cell corresponding to the lowest level cells of the branches.

14. The method of claim 8 comprises:
analyzing results of inspecting the wafer;
adjusting an inspection recipe of the inspection tool to decrease capturing of nuisances.

15. The method of claim 14 wherein analyzing and adjusting the inspection recipe is repeated until nuisances are masked off the inspection results.

16. A computer program storage medium comprising:
a program with instructions to determine care areas of a layout of a device, the instructions include
reading an artwork file containing the layout of the device,
creating a hierarchical cell tree which is a logical representation of the cells of the device, and
identifying the care areas of the device from the cell tree.

17. The computer program storage medium of claim 16 wherein instructions for creating the hierarchical cell tree comprise:
determining a top level cell of the layout; and
determining child cells of the top level cell, wherein the top level cell comprises 1 to n child cells, where n is greater or equal to 2, wherein one child cell represents one branch of the tree branches from the top level cell.

18. The computer program storage medium of claim 16 wherein instructions for identifying care areas comprise generating polygons in the top level cell corresponding to the lowest level cells of the branches.

19. The computer program storage medium of claim 16 wherein instructions for creating the hierarchical cell tree comprise:
determining a top level cell of the layout; and
determining child cells of the top level cell.

20. The computer program storage medium of claim 16 wherein instructions for identifying care areas comprise generating polygons in the top level cell corresponding to the child cells.
